(19) United States
(12) Patent Application Publication
(10) Pub. No.: US 2014/0295196 A1
(43) Pub. Date: Oct. 2, 2014

(54) COMPOSITE FILM AND MANUFACTURING METHOD OF THE SAME

(71) Applicant: INDUSTRIAL TECHNOLOGY RESEARCH INSTITUTE, Hsinchu (TW)

(72) Inventors: Mao-Yuan CHIU, Yuli Township (TW); Jui-Hung HSU, Changhua City (TW); Dan-Cheng KONG, Taibao City (TW)

(73) Assignee: INDUSTRIAL TECHNOLOGY RESEARCH INSTITUTE, Hsinchu (TW)

(21) Appl. No.: 14/082,027

(22) Filed: Nov. 15, 2013

(30) Foreign Application Priority Data
Mar. 29, 2013 (TW) 102111520

(51) Int. Cl. B32B 27/08; C23C 16/455; B29C 47/06

(52) U.S. Cl. CPC B32B 27/08; B29C 47/065; C23C 16/45525
USPC 428/516; 264/129

(57) ABSTRACT

A composite film and a manufacturing method of the same are provided. The composite film includes an organic multilayer film and two inorganic gas barrier layers. The organic multilayer film comprises a hydrophobic polymer layer and two hydrophilic polymer layers formed on two opposite surfaces of the hydrophobic polymer layer, respectively. The two inorganic gas barrier layers are formed on the two hydrophilic polymer layers, respectively.

This application claims the benefit of Taiwan application Serial No. 102111520, filed Mar. 29, 2013, the disclosure of which is incorporated by reference herein in its entirety.

### TECHNICAL FIELD

The disclosure relates to a composite film and a manufacturing method of the same.

### BACKGROUND

In recent years, as the market is getting more interested and focused in the portability and flexibility properties of consumer electronic products, the development of flexible electronic products has drawn extensive attention. Since flexible electronic products have advantages of lightweight and toughness and can be nicely spread on a curved surface, the current optoelectronic devices may have a wider and brand new application in fields such as energy, display and illumination.

Normally, the flexible electronic devices use a plastic film or a metal thin film as a substrate material. In comparison to a metal-based substrate, the plastic substrate advantageously possesses higher transparency and flexibility, and is likely to become the mainstream of flexible substrates.

However, the plastic substrates have poor performance in blocking water vapor and oxygen, such that the functional layers and the electrodes with low work function in the optoelectronic devices may easily react with water vapor and oxygen in the air and result in device degradation, which is a severe problem in the development of flexible electronic products. Therefore, how to provide a substrate film having the features of transparency and flexibility and at the same time being capable of blocking water vapor and oxygen has become a crucial task in the development of flexible electronic products.

### SUMMARY

The disclosure is directed to a composite film and a manufacturing method of the same. The organic multilayer film, formed by the disposition of two hydrophilic polymer layers formed on two opposite surfaces of the hydrophobic polymer layer and the disposition of the inorganic gas barrier layers on the hydrophilic polymer layers, provides excellent water vapor and oxygen barrier properties. Furthermore, the adhesion of the inorganic gas barrier layers on the organic multilayer film is enhanced, defect density is reduced, and excellent overall water vapor/oxygen barrier effect is achieved.

According to one embodiment, a composite film is provided. The composite film comprises an organic multilayer film and two inorganic gas barrier layers. The organic multilayer film comprises a hydrophobic polymer layer and two hydrophilic polymer layers. The two hydrophilic polymer layers are formed on two opposite surfaces of the hydrophobic polymer layer, respectively. The two inorganic gas barrier layers are formed on the top surfaces of the two hydrophilic polymer layers, respectively.

According to another embodiment, a manufacturing method of composite film is provided. The manufacturing method of the composite film comprises: forming an organic multilayer film by a co-extrusion process, wherein the organic multilayer film comprises a hydrophobic polymer layer and two hydrophilic polymer layers formed on two opposite surfaces of the hydrophobic polymer layer, respectively; and forming two inorganic gas barrier layers on the top surface of two hydrophilic polymer layers, respectively.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a schematic diagram of a composite film according to an embodiment of the present disclosure.

FIGS. 2A-2C show processes of a manufacturing method of a composite film according to an embodiment of the present disclosure.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

A composite film is disclosed according to the embodiments of the present disclosure. The organic multilayer film, formed by the disposition of two hydrophilic polymer layers on two opposite surfaces of the hydrophobic polymer layer and the disposition of the inorganic gas barrier layers on the hydrophilic polymer layers, provides excellent water vapor and oxygen barrier properties. Furthermore, the adhesion of the inorganic gas barrier layers on the organic multilayer film is enhanced, defect density is reduced, and excellent overall water vapor/oxygen barrier effect is achieved. A number of embodiments are disclosed below for elaborating the present disclosure with reference to accompanying drawings. Common reference numerals are used throughout the drawings and the detailed description to indicate the same elements. It should be noted that the drawings are simplified for clearly elaborating the present disclosure, and detailed structure of the embodiments are for exemplification purpose only, not for limiting the scope of protection of the present disclosure. Anyone who is skilled in the technology of the present disclosure can make modification or adjustment to the structures according to the needs in actual implementations.

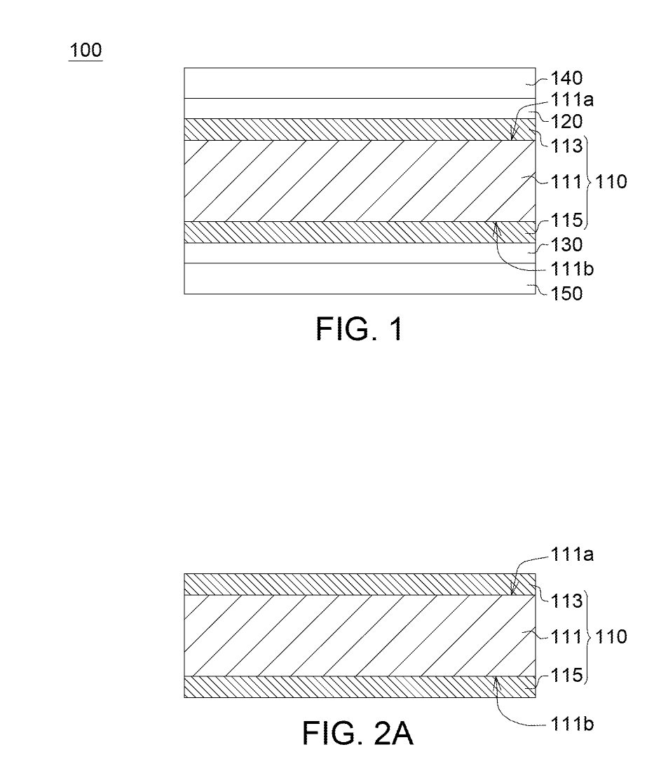

FIG. 1 shows a schematic diagram of a composite film 100 according to an embodiment of the present disclosure. As indicated in FIG. 1, the composite film 100 comprises an organic multilayer film 110 and two inorganic gas barrier layers 120 and 130. The organic multilayer film 110 comprises a hydrophobic polymer layer 111 and two hydrophilic polymer layers 113 and 115. The hydrophilic polymer layers 113 and 115 are formed on two opposite surfaces 111a and 111b of the hydrophobic polymer layer 111, respectively. The inorganic gas barrier layers 120 and 130 are formed on the top surfaces of the hydrophilic polymer layers 113 and 115, respectively.

In an embodiment, the thickness of the hydrophobic polymer layer 111 is 10-200 micrometer (μm) or 50-150 μm; the thickness of the hydrophilic polymer layers 113 and 115 is 1-20 μm or 10-15 μm.

In an embodiment, the material of the hydrophobic polymer layer 111 comprises a grafted hydrophobic polymer. In comparison to the non-grafted hydrophobic polymer, the grafted hydrophobic polymer has higher polarity, and provides better adhesion between the hydrophobic polymer layer 111 and the hydrophilic polymer layers 113 and 115. As such, as indicated in FIG. 1, the hydrophobic polymer layer 111 can be in direct contact with the hydrophilic polymer layers 113 and 115, between which layers no extra adhesive layer is needed. For example, the grafted functional group(s) of the grafted hydrophobic polymer may have high polarity, or the polarity of the hydrophobic polymer is increased after the polymer is grafted.

In an embodiment, the grafting ratio of the grafted hydrophobic polymer is 0.5-8%. This ratio is crucial. When the grafting ratio is lower than 0.5%, the overall polarity of the polymer will be too low, hence resulting in poor adhesion between the hydrophobic polymer layer 111 and the hydrophilic polymer layers 113 and 115. When the grafting ratio is higher than 8%, the molecular weight of the hydrophobic polymer will be too low, hence incapacitating film formation.

In the embodiment, the hydrophobic polymer layer 111 has excellent water vapor barrier properties, and the hydrophilic polymer layers 113 and 115 have excellent oxygen barrier properties. The hydrophobic polymer layer 111, together with the hydrophilic polymer layers 113 and 115, can provide excellent water vapor/oxygen barrier properties. In the embodiment, both the hydrophobic polymer layer 111 and the hydrophilic polymer layers 113 and 115 have high transparency, and these layers are formed from one or more transparent materials which may be the same or different from one another.

In the embodiment, the material of the hydrophobic polymer layer 111 comprises at least one of maleic anhydride grafted polypropylene (PP-g-MA), glycidyl methacrylate grafted polypropylene (PP-g-GMA), maleic anhydride grafted ethylene-propylene copolymer, glycidyl methacrylate grafted ethylene-propylene copolymer, or the combinations thereof.

In an embodiment, the materials of the hydrophilic polymer layers 113 and 115 independently and respectively comprise at least one of ethylene copolymer, propylene copolymer, ethylene vinyl alcohol (EVOH), polyamide, acrylonitrile-methyl methacrylate copolymer, styrene-acrylonitrile copolymer, or the combinations thereof.

In an embodiment, the composite film 100 may further comprise a desiccant mixed in the hydrophobic polymer layer 111. In an embodiment, the weight percentage of the desiccant in the hydrophobic polymer layer 111 is 1-5 wt %. The existence of the desiccant prevents the water contained in the polymer material from generating micro-bubbles in co-extrusion processes and affecting the quality of the organic multilayer film 110 and provides an additional water vapor barrier mechanism.

In an embodiment, the material of the desiccant may be an inorganic powder comprising at least one of calcium oxide, calcium hydroxide, calcium chloride, calcium sulfate, magnesium sulfate, or the combinations thereof or comprising a masterbatch formed by mixing the above-mentioned inorganic powder in polyethylene, polypropylene or ethylene-vinyl acetate copolymer. In an embodiment, the weight percentage of inorganic species in a masterbatch is 60-80 wt %. The desiccant must exist in the hydrophobic polymer layer 111. If the desiccant is added to the hydrophilic polymer layers 113 and 115, the desiccant may affect the surface roughness of the hydrophilic polymer layers 113 and 115 as well as subsequent formation of inorganic gas barrier layers.

In an embodiment, as indicated in FIG. 1, the inorganic gas barrier layers 120 and 130 are in direct contact with the hydrophilic polymer layers 113 and 115, respectively, between which no extra adhesive layer is needed. In the embodiment, the hydrophilic polymer layers 113 and 115 are formed on the external surfaces of the hydrophobic polymer layer 111, and the inorganic gas barrier layers 120 and 130 are directly formed on the hydrophilic surfaces of the hydrophilic polymer layers 113 and 115. The chemical structures of the hydrophilic polymer layers 113 and 115 contain polar functional groups, such as hydroxyl group (OH group), cyano group (CN group), carbonyl group (CO group) and/or amino group (NHₓ group), which can better absorb hydrophilic precursors (such as metal complexes) used in the film deposition process of the inorganic gas barrier layers 120 and 130. Therefore, the inorganic gas barrier layers 120 and 130 can be formed without performing extra chemical or physical surface treatments on the surfaces of the hydrophilic polymer layers 113 and 115. Meanwhile, the defects of the inorganic gas barrier layers 120 and 130 are reduced, and the water vapor/oxygen barrier effect is enhanced. In other words, the adhesion between the inorganic gas barrier layers 120 and 130 and the hydrophilic polymer layers 113 and 115 is enhanced (in comparison to the hydrophobic polymer layer 111). Given that the hydrophilic polymer layers 113 and 115 covering the surfaces of the hydrophobic polymer layer 111 provides excellent water vapor/oxygen barrier effect, and the adhesion of the inorganic gas barrier layers 120 and 130 formed on the organic multilayer film 110 is further increased, therefore, the organic multilayer film 110 can thus provide better water vapor/oxygen barrier effect.

In the embodiment, the inorganic gas barrier layers 120 and 130 are transparent metallic oxide layers with high transparency. The materials of the inorganic gas barrier layers 120 and 130 comprise one or more transparent materials which may be the same or different from each other. The materials of the inorganic gas barrier layers 120 and 130 respectively and independently comprise at least one of aluminum oxide, zinc oxide, zirconium oxide, hafnium oxide, indium nitride, or the combinations thereof.

In the embodiment, as indicated in FIG. 1, the composite film 100 may further comprise two protection layers 140 and 150 formed on the inorganic gas barrier layers 120 and 130, respectively. There is excellent adhesion between the protection layers 140 and 150 and the inorganic gas barrier layers 120 and 130. The protection layers 140 and 150, being scratch proof and flexible, provide physical protection to the inorganic gas barrier layers 120 and 130 from being scratched or broken, and help to prevent the inorganic gas barrier layers 120 and 130 from reacting with the water vapor and oxygen in the air and becoming deteriorated.

In an embodiment, the materials of the protection layers 140 and 150 respectively and independently comprise at least one of urethane acrylate, epoxy acrylate, polyacrylate, polyester, or combinations thereof. In an embodiment, the thickness of the protection layers 140 and 150 is 1-8 μm or 1-5 μm.

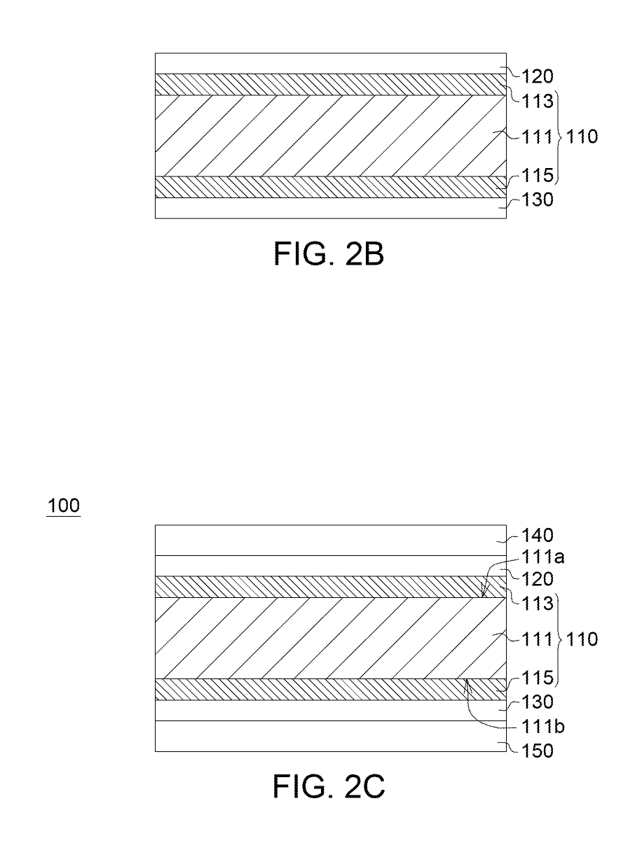

Detailed procedures of a manufacturing method of the package structure 100 are elaborated in a number of embodiments below. However, the procedures elaborated in the embodiments are for exemplification purpose only, not for limiting the scope of protection of the present disclosure. Anyone who is skilled in the technology of the present disclosure can make modification or adjustment to the structures according to the needs in actual implementations. Referring to FIGS. 2A-2C, processes of a manufacturing method of a composite film according to an embodiment of the present disclosure are shown.

Referring to FIG. 2A, an organic multilayer film 110 is formed. The method of forming the organic multilayer film 110 comprises the steps of: forming a hydrophobic polymer layer 111; and forming two hydrophilic polymer layers 113 and 115 on two opposite surfaces 111a and 111b of the hydrophobic polymer layer 111, respectively.

In an embodiment, the organic multilayer film 110 is formed by a co-extrusion process, wherein the temperature of melting extrusion is 220-240° C. The co-extrusion process is different from ordinary lamination process of manufacturing a multilayer film structure in that the organic multilayer film 110 with multilayer structure is integrally formed in one step, such that the multilayer structure can be tightly bonded without using any extra adhesive layer. Therefore, the manufacturing process is simplified and the manufacturing cost is reduced by forming the organic multilayer film 110 by a co-extrusion process.

In an embodiment, the materials of the hydrophilic polymer layers and the hydrophobic polymer layer are respectively infused to a single screw extruder, co-extruded to a coat-hanger die, and cooled by a casting drum to obtain an organic multilayer film 110 with a structure composed of hydrophilic polymer layer 113/hydrophobic polymer layer 111/hydrophilic polymer layer 115 in a top down manner. The operating temperature of the extruder is 220° C.-240° C., and the operating temperature of the casting drum is 15° C.-40° C. In the co-extrusion process, the desiccant can be added to the hydrophobic polymer layer 111.

In an embodiment, the material of the hydrophobic polymer layer 111 comprises a grafted hydrophobic polymer, which helps to enhance the adhesion between the hydrophobic polymer layer 111 and the hydrophilic polymer layers 113 and 115. In the embodiment, during the formation of the hydrophobic polymer layer 111, a desiccant can be mixed in the hydrophobic polymer layer 111 to increase the water vapor/oxygen barrier effect for preventing the water contained in the high polymer material from generating micro-bubbles in the subsequent co-extrusion process and affecting the quality of the coextruded organic multilayer film 110.

In an embodiment, the materials of the hydrophilic polymer layers 113 and 115 comprise, such as, ethylene vinyl alcohol (EVOH). The molar ratio of ethylene in the copolymer is 32-48 mol %, such that the composite film 110 has excellent oxygen barrier effect, and the film formation becomes easier. The above ratio is crucial. When the molar ratio of ethylene in the copolymer is lower than 32 mol %, film formation becomes difficult. When the molar ratio of ethylene is higher than 48 mol %, film formation becomes easier but oxygen barrier performance deteriorates dramatically.

Next, referring to FIG. 2B, two inorganic gas barrier layers 120 and 130 are formed on the hydrophilic polymer layers 113 and 115, respectively.

In the embodiment, as indicated in FIG. 2B, the inorganic gas barrier layers 120 and 130 are in direct contact with the hydrophilic polymer layers 113 and 115, respectively. The hydrophilic polymer layers 113 and 115 can reduce the defect density and enhance the adhesion of the inorganic gas barrier layers 120 and 130 during film deposition. Therefore, in addition to the water/oxygen barrier properties, the water vapor/oxygen barrier effect of the organic multilayer film 110 is largely increased through the deposition of the inorganic gas barrier layers.

In the embodiment, the inorganic gas barrier layers 120 and 130 are formed on the hydrophilic polymer layers 113 and 115 by such as a thermal evaporation process, a sputtering process, chemical vapor deposition (CVD), or atomic layer deposition (ALD).

In an embodiment, the inorganic gas barrier layers 120 and 130 can be formed by atomic layer deposition, and available precursors are such as trimethyl aluminum and water. The inorganic gas barrier layers 120 and 130 are deposited by an atomic layer deposition machine and the reacting temperature is 100-150° C. The thickness of the inorganic gas barrier layers 120 and 130 is 120-200 atomic layers or between 180-200 atomic layers, such that the inorganic gas barrier layers 120 and 130 have excellent flexibility and do not crack easily. In addition, in comparison to the structure formed by physical vapor deposition, the structure formed by atomic layer deposition has a very low pinhole density and fewer defects, and can provide better water vapor/oxygen barrier effect.

Next, referring to FIG. 2C, two protection layers 140 and 150 are formed on two inorganic gas barrier layers 120 and 130, respectively.

The method of manufacturing protection layers 140 and 150 comprises the steps of: coating photo-curable protection layers on the surfaces of the inorganic layers 120 and 130; and irradiating the photo-curable protection layers with an ultraviolet (UV) light, such that crosslinking reactions occur in the photo-curable protection layers and the photo-curable protection layers are cured to form the protection layers 140 and 150. Thus, the composite film 100 of FIG. 2C (FIG. 1) is formed.

The materials, structural disposition and characteristics of the composite film are disclosed below in a number of embodiments. However, these embodiments are for exemplification purpose only, not for limiting the scope of protection and implementation of the present disclosure.

The disclosed composite film according to the embodiments is transparent.

The composite film according to the embodiments of the disclosure can be used as a substrate material or a package film in a flexible electronic apparatus, a thin film solar cell, or an organic solar cell.

### Embodiment 1

An EVOH/PP-g-MA/EVOH organic multilayer film is formed by a co-extrusion process. The organic multilayer film comprises a hydrophobic polymer layer 111 formed of maleic anhydride grafted polypropylene (PP-g-MA), and two hydrophilic polymer layers 113 and 115 formed of ethylene vinyl alcohol (EVOH). The thickness of the hydrophilic polymer layers 113 and 115 (EVOH) is 15 μm, and the molar ratio of ethylene is 38 mol % in EVOH. The thickness of the hydrophobic polymer layer 111 (PP-g-MA) is 110 μm. Next, trimethyl aluminum and water are used as precursors in the atomic layer deposition process, and 200 atomic layers of aluminum oxide are deposited by an atomic layer deposition machine at an operating temperature of 120° C. to form the inorganic gas barrier layers. Then, an acrylic photo-curable coating as the protection layer is applied on the top surface of each inorganic gas barrier layer by a coating machine with meyer rod, or gravure roll, and the photo-curable coating is irradiated with a UV light to be cured to form protection layers. After the composite film is formed, its water vapor transmission rate (WVTR) is obtained by using the ASTM F1249 testing method, oxygen transmission rate (OTR) is obtained by using the ASTM D3985 testing method, and full wavelength light transmittance is obtained by using the ASTM D1003 testing method.

### Embodiment 2

The manufacturing method of embodiment 2 is basically the same with that of embodiment 1, except that in the present embodiment, the molar ratio of ethylene is 44 mol % in EVOH. Similarly, after the composite film is formed, its water vapor transmission rate, oxygen transmission rate and full wavelength light transmittance are obtained by way of measurement.

### Embodiment 3

The manufacturing method of embodiment 3 is basically the same with that of embodiment 1 except that in the present embodiment, a desiccant is mixed in the hydrophobic polymer layer 111 formed of maleic anhydride grafted polypropylene (PP-g-MA). The material of the hygroscopic agent comprises a masterbatch consisting of 80 wt % of calcium oxide and 20 wt % of polyethylene. The desiccant is added to the hydrophobic polymer layer 111, such that the weight percentage of calcium oxide becomes 4 wt %. Similarly, after the composite film is formed, its water vapor transmission rate, oxygen transmission rate and full wavelength light transmittance are obtained by way of measurement.

### Embodiment 4

The manufacturing method of embodiment 4 is basically the same as that of embodiment 3, except that in the present embodiment, the molar ratio of ethylene is 44 mol % in EVOH. Similarly, after the composite film is formed, its water vapor transmission rate, oxygen transmission rate and full wavelength light transmittance are obtained by way of measurement.

TABLE 1

| | Water Vapor | Oxygen | Full |
|---|---|---|---|
| | Transmission | Transmission | Wavelength |
| | Rate | Rate | Light |
| | (g/m²-day) | (cc/m²-day-atm) | Transmittance |
| | (90% RH, 40 ° C.) | (0% RH, 23 ° C.) | (%) |
| Embodiment 1 | 0.088 | <0.01 | 92.21 |
| Embodiment 2 | 0.054 | <0.01 | 91.20 |
| Embodiment 3 | 0.070 | <0.01 | 83.10 |
| Embodiment 4 | 0.041 | <0.01 | 81.45 |

Table 1 shows that in embodiments 1-4, all oxygen transmission rates of the composite films are less than 0.01 cc/m²-day-atm, all water vapor transmission rates are less than 0.10 g/m²-day, and all full wavelength light transmittances are higher than 80%. As indicated in Table 1, the composite film of each embodiment of the present disclosure has excellent water vapor/oxygen barrier effect and high transmittance of the light.

The composite film disclosed in the above embodiments of the present disclosure comprises organic layers and inorganic layers, has high transparency, flexibility and high barrier effect for water vapor and oxygen and can be used as a substrate material or package film in a flexible electronic apparatus, thin film solar cell or organic solar cell. Moreover, the composite film of the present disclosure can be directly deposited on application components and packaged by way of coating or lamination without adopting high-precision manufacturing process, and is simple and convenient in terms of use.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A composite film, comprising:
an organic multilayer film, comprising:
a hydrophobic polymer layer; and
two hydrophilic polymer layers formed on two opposite surfaces of the hydrophobic polymer layer, respectively; and
two inorganic gas barrier layers formed on the two hydrophilic polymer layers, respectively.

2. The composite film according to claim 1, wherein the hydrophobic polymer layer is in direct contact with the hydrophilic polymer layers.

3. The composite film according to claim 1, wherein the material of the hydrophobic polymer layer comprises a grafted hydrophobic polymer.

4. The composite film according to claim 3, wherein the grafting ratio of the grafted hydrophobic polymer is 0.5-8%.

5. The composite film according to claim 1, wherein the material of the hydrophobic polymer layer comprises at least one of maleic anhydride grafted polypropylene (PP-g-MA), glycidyl methacrylate grafted polypropylene (PP-g-GMA), maleic anhydride grafted ethylene-propylene copolymer, glycidyl methacrylate grafted ethylene-propylene copolymer, or the combinations thereof.

6. The composite film according to claim 1, wherein the material of the hydrophilic polymer layers comprises at least one of ethylene copolymer, propylene copolymer, ethylene vinyl alcohol (EVOH), polyamide, acrylonitrile-methyl methacrylate copolymer, styrene-acrylonitrile copolymer, or the combinations thereof.

7. The composite film according to claim 1, wherein the inorganic gas barrier layers are in direct contact with the hydrophilic polymer layers, respectively.

8. The composite film according to claim 1, wherein the materials of the inorganic gas barrier layers comprise at least one of aluminum oxide, zinc oxide, zirconium oxide, hafnium oxide, indium nitride, or the combinations thereof.

9. The composite film according to claim 1, further comprising two protection layers formed on the two inorganic gas barrier layers.

10. The composite film according to claim 9, wherein the materials of the protection layers comprise at least one of urethane acrylate, epoxy acrylate, polyacrylate, polyester, or the combinations thereof.

11. The composite film according to claim 1, further comprising a desiccant mixed in the hydrophobic polymer layer.

12. The composite film according to claim 11, wherein the material of the desiccant comprises at least one of calcium oxide, calcium hydroxide, calcium chloride, calcium sulfate, magnesium sulfate, or the combinations thereof.

13. The composite film according to claim 11, wherein the material of the desiccant comprises a masterbatch which is formed by mixing at least one of calcium oxide, calcium hydroxide, calcium chloride, calcium sulfate, magnesium sulfate, or the combinations thereof in polyethylene, polypropylene or ethylene-vinyl acetate copolymer.

14. The composite film according to claim 1, wherein the water vapor transmission rate of the composite film is less than 0.10 g/m²-day, the oxygen transmission rate of the composite film is less than 0.01 cc/m²-day-atm, and all wavelength light transmittances of the transparent composite film are higher than 80%.

15. A manufacturing method of a composite film, comprising:
forming an organic multilayer film by a co-extrusion process, comprising:
forming a hydrophobic polymer layer; and
forming two hydrophilic polymer layers on two opposite surfaces of the hydrophobic polymer layer, respectively; and
forming two inorganic gas barrier layers with atomic layer deposition method on the two hydrophilic polymer layers, respectively.

16. The manufacturing method of the composite film according to claim 15, wherein the material of the hydrophobic polymer layer comprises a grafted hydrophobic polymer.

17. The manufacturing method of the composite film according to claim 15, further comprising:
forming two protection layers on top surfaces of the two inorganic gas barrier layers, respectively.

18. The manufacturing method of the composite film according to claim 15, further comprising:
mixing a desiccant in the hydrophobic polymer layer.

19. The manufacturing method of the composite film according to claim 15, wherein the inorganic gas barrier layers are formed on the hydrophilic polymer layers by a thermal evaporation process, a sputtering process, chemical vapor deposition, or atomic layer deposition (ALD).

20. The manufacturing method of the composite film according to claim 15, wherein the inorganic gas barrier layers are in direct contact with the hydrophilic polymer layers, respectively.

21. The manufacturing method of the composite film according to claim 15, further comprising:
disposing the composite film as a substrate material or a package film in a flexible electronic apparatus, a thin film solar cell, or an organic solar cell.
